(19) United States
(12) Patent Application Publication
(10) Pub. No.: US 2004/0155281 A1
(43) Pub. Date: Aug. 12, 2004

(54) Semiconductor device formed on a SOI substrate

(76) Inventors: Kenichi Osada, Tokyo (JP); Takayuki Kawahara, Higashiyamato (JP); Masanao Yamaoka, Hachioji (JP)

Correspondence Address: MATTINGLY, STANGER & MALUR, P.C., SUITE 370, 1800 DIAGONAL ROAD, ALEXANDRIA, VA, 22314, US

(21) Appl. No.: 10/720,249

(22) Filed: Nov. 25, 2003

(30) Foreign Application Priority Data
Dec. 9, 2002 (JP) 2002-356127
Nov. 11, 2003 (JP) 2003-381083

(51) Int. Cl. H01L 29/788

(52) U.S. Cl. 257/315

(57) ABSTRACT

Thresholds of MISFETS of a Full Depletion-type SOI substrate cannot be controlled by changing impurity density as with bulk silicon MISFETs. Therefore, it is difficult to set a suitable threshold for each circuit. According to the semiconductor device of the present invention, gate electrodes of P-channel type MISFETs composing a memory cell are made of N-type polysilicon, gate electrodes of N-channel type MISFETs are made of P-type polysilicon and gate electrodes of P-channel type and N-channel type MISFETs of peripheral circuits and a logic circuit are made of P-type silicon germanium. A suitable threshold can be achieved for each circuit using a SOI substrate, thereby making it possible to fully leverage the characteristics of the SOI substrate.

The present application claims priority from Japanese application JP2002-356127 filed on Dec. 9th, 2003, and from Japanese application JP2003-381083 filed on Nov. 11th, 2003, the content of which are hereby incorporated by reference into this application.

### BACKGROUND OF THE INVENTION

1. Field of the Invention

The present invention relates to a semiconductor device and, in particular, to devices including an on-chip memory, a microprocessor, and a system LSI, all of which have a Static Random Access Memory (SRAM) mounted thereon.

2. Description of Related Art

In JP-A No.53168, a static-type RAM formed on a semiconductor on insulator (hereafter, simply referred to as SOI) substrate, and P-type well regions, in which a N-channel MOSFET of memory cells are formed independently for a separate subword line is disclosed. The P-type well regions, are inflicted with relatively low well voltage when its corresponding subword line is not selected, and are inflicted with relatively high well voltage when its corresponding subword line is selected.

In JP-A No.106579, an integrated circuit realizing low leakage current during low power operation, and large current during high operation by changing the thickness of the SOI layer or the thickness of a gate insulating film to control MOSFET threshold voltage, and by inflicting a voltage on the insulating electrode of the silicon substrate to change threshold voltage, is disclosed. The document also depicts that changing metal materials of the gate electrode is effective for changing threshold voltage.

In JP-A No.36037, the gate electrode of the PMOS transistor formed in a logic portion on the SOI base substrate is formed as a P-type gate electrode while the gate electrode of the PMOS transistor in a cell portion of DRAM on the SOI base substrate is formed as a N-type electrode, respectively.

In JP-A No.303385, the silicon substrate is exposed by selectively removing a silicon layer and an insulation layer of the SOI substrate, and on the exposed part of the silicon substrate a DRAM memory cell portion is formed and on the silicon layer, a DRAM logic circuit is formed. To increase the threshold of an access transistor in the memory cell, a substrate bias is applied to the well on the silicon substrate

In JP-A No.213562, a device structure of DRAM having a SOI region and a silicon substrate region, where the memory cell portion is formed in the SOI region and the logic circuit portion and the I/O circuit portion are formed in the silicon substrate region, is disclosed.

Prior to this invention, the inventors of the present invention discussed about possible problems which would occur at the stage when the semiconductor miniaturized even at a lower voltage.

In large scale integration (hereafter, simply referred to as LSI) systems, it is becoming more important to lower power consumption and to lower leakage current, and the internal voltage of the processor will be further lowered. In the future, it is also required for SRAM mounted on the processor to operate at a low voltage ranging from about 0.2 to about 0.6 V. At low voltage, operation margin for write/read operation is reduced, and in the case of the semiconductor bulk device using processes of under 0.08 um, dispersions of threshold voltages have a great effect on device operation, thereby it is difficult for a SRAM cell to operate stably. Meanwhile, the threshold voltage is hard to reduce because leakage current may increase, causing the operation speed to drop at a low speed. In addition, resistance to soft errors noticeably deteriorates.

SOI(Semiconductor On Insulator)s, especially full depletion-type SOI substrates, can reduce the dispersion of threshold voltage caused during ion implantation in the bulk silicons, enabling the device to stably operate at a low voltage. Moreover, since the subthreshold factor of the transistor is small, even though the threshold voltage is lower, the leakage current does not increase, which allows to achieve high-speed device operation at a low voltage. Furthermore, the channel region, in which electric charges generate, is relatively small, which improves the resistance to soft errors. For this reason, the SOI substrate is expected to be a next-generation technology to solve the problems involved with the bulk silicon wafer.

In the case of the Full Depletion-type SOI, however, it is difficult to form the MISFET (Metal Insulator Semiconductor Field Effect Transistor) with a most favorable threshold. As shown in FIG. 13, for example, for the SRAMs required to operate at a high speed of 300 MHz or more (HIGH SPEED), the required threshold voltage VT for P-type MISFETs is about −0.5 to −0.3 V and for N-type MISFETs is about 0.2 to 0.4 V in the memory cell portion; and for P-type MISFETs is about −0.3 to −0.1 V and for N-type MISFETs is about 0.1 to 0.3 V in the logic portion. Similarly, for standard SRAMs (STANDARD) of 100 to 300 MHz and SRAMs requiring low power and operate at lower than 100 MHz (LOW POWER), MISFETs having a given threshold voltage most suitable for device operation is required. As shown in FIG. 14, however, the P channel-type MISFETs having the gate electrodes formed of polysilicon which have P-type dopants implanted and the N channel-type MISFETs having the gate electrodes formed of polysilicon which have N-type dopants implanted, which are commonly used, cannot produce MISFETs with threshold voltages necessary for an operatable device. For MISFETs fabricated on a bulk, threshold voltages can be easily controlled by varying the concentration of the dopants implanted into the channel region, while MISFETs fabricated on SOIs have a problem that its threshold voltages are difficult to change even by varying the concentration of the dopants implanted into the channel region, as well as the thickness of an oxide film and the ratio of the channel length to the channel width.

Besides, the SOI has another problem that in contrast to the MISFET formed on the bulk, for which a substrate potential is coupled to a source potential or a ground potential, the potential of the region forming the channel is not controlled and is in a floating state, and thereby tends to be vulnerable against noise. The potential of the channel formation region may be controlled to solve these problems involved with the SOI. But even for the same conductivity type MISFET, the channel region is separated, thereby a power supply part is needed for each MISFET, thereby increasing space requirement.

### SUMMARY OF THE INVENTION

One object of the present invention is to provide MISFETs having threshold voltages required from the circuit operation for a semiconductor device using a SOI substrate. Another object of the present invention is to provide a semiconductor device mounted with a SRAM memory and using SOI substrates which has ensured stable operation while suppressing an increase in space requirement.

Now, typical embodiments of the present invention disclosed in this specification are briefly described.

For SRAM memory cells, the regions forming the channels of the drive MISFETs are in a floating state, while the regions forming the channel of the transfer MISFETs are controlled. Especially by using Dynamic-Threshold-Voltage Metal Oxide Semiconductor Field Effect Transistor (hereafter, simply referred to as a DTMOSFET)s, which the channel regions and the gate electrodes are coupled, for transfer MISFETs, data can be read out from. the selected memory cell at a high speed.

In the semiconductor layer under the insulation layer of the SOI substrate, the power supply portion having a higher concentration of impurities than that of the semiconductor layer is formed, and a voltage is applied to the power supply part to adjust the threshold voltages of an element formed on the SOI substrate.

On the hybrid substrate, the power supply part and the input and output circuit, the analog circuit, and the switch circuit controlling the operating voltage of the circuits formed on the SOI portion are formed in the bulk portion and the SRAM memory cell and the logic circuit are formed in the SOI portion.

For hybrid substrates and SOI substrates with no bulk portion, by changing the conditions of the voltage inflicted to the semiconductor layer under the insulating layer of the SOI substrate, the gate electrode material, and the conductivity type of the dopants implanted into the gate electrode, a MISFET having a threshold voltage required for the semiconductor device is formed.

For 4TSRAM memory cells formed on the SOIs, the channel region of the transistor, in which the gate is connected a word line and the source-drain path is connected between one of a pair of bit lines and one of the drains of the two drive transistors, is controlled by the output of the other of the two drive transistors.

The MISFETs formed on the SOI layer is used for the power switch of the logic circuit and the two gates controlling its channel region are controlled by applying the same voltage. This means that DTMOSs formed on the SOIs are used for power switches.

The transistors in the circuit which uses a plurality of power systems are formed on a common SOI base substrate.

These and other objects, features and advantages of the present invention will become more apparent in light of the following detailed description of the preferred embodiments in conjunction with the drawings identified in the following Brief Description of the Drawings.

### BRIEF DESCRIPTION OF THE DRAWINGS

FIG. 1 is a schematic diagram of a semiconductor device according to the first embodiment

FIG. 2 is a view of operating waveforms of the semiconductor device according to the first embodiment.

FIG. 3 is a schematic diagram of the semiconductor device according to the first embodiment.

FIG. 4 is a schematic view of the cross-section of the semiconductor device according to the first embodiment.

FIG. 5 is a block diagram of the semiconductor device according to the second embodiment.

FIG. 6 is a schematic diagram of the semiconductor device according to the second embodiment.

FIG. 7 is a schematic view of the cross-section of the semiconductor device according to the second embodiment.

FIG. 8 is a block diagram of the semiconductor device according to another embodiment of the second embodiment.

FIG. 9 is a block diagram of the semiconductor device according to the third embodiment.

FIG. 10 is a schematic view of the semiconductor device according to the third embodiment.

FIG. 11 is a schematic view of the cross section of the semiconductor device according to the third embodiment.

FIG. 12 is an embodiment of a threshold voltage suitable for each circuit.

FIG. 13 is threshold voltages required by the semiconductor devices mounting a SRAM memory cell.

FIG. 14 is a threshold voltage of the MISFET formed on a SOI substrate.

FIG. 15 is a dynamic threshold voltage control on the SOI substrate.

FIG. 16 is a schematic view of the cross section of the semiconductor device according to the fourth embodiment.

FIG. 17 is a schematic diagram of the semiconductor device according to the fifth embodiment.

FIG. 18 is a schematic view of the cross section of the semiconductor device according to the sixth embodiment.

FIG. 19 is a layout of the semiconductor device according to the sixth embodiment.

### DETAILED DESCRIPTION OF THE PREFERRED EMBODIMENTS

The following is a detailed description of the preferred embodiments of the present invention with reference to the appended drawings.

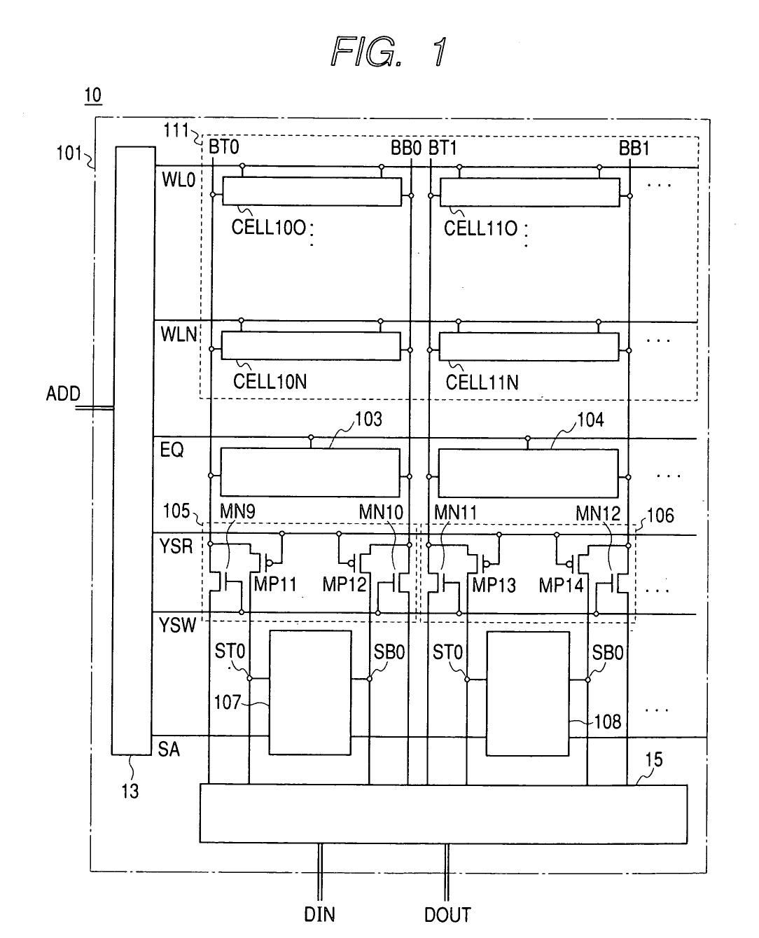

FIG. 1 is a circuit view showing one embodiment of the semiconductor device of the present invention. The chip 10 mounted with SRAM memory cells, a semiconductor device, shows a portion of a semiconductor integrated circuit and is formed on a semiconductor substrate 101, where at least SRAM memory array 111 is formed on the Semiconductor On Insulator (SOI) substrate.

The memory array 111 is laid out on a matrix form having a plurality of SRAM memory cells (CELL) disposed at the intersections between a plurality of bit lines (BT, BB) and a plurality of word lines (WL). The control circuit 13 includes a decoder circuit and word driver circuit, where when an address signal ADD is inputted, the address signal is decoded by the decoder circuit, and based on the decoded signal, the word driver circuit selects one of the plurality of the word lines (WL). The control circuit 117 also generates pre-charge/equalize circuit control signal EQ, read Y switch control signal YSR, write Y switch control signal YSW, sense amplifier control signal SA, each of which is output to its associated circuit. Bit lines are connected to the sense amplifier circuits (107, 108), the pre-charge/equalize circuits (103, 104), and the Y switch circuits (105, 106), and data written in externally (DIN) and data externally read out (DOUT) is processed through the data input and output circuit (15). The data input and output circuit (15) has an input and output buffer circuit and a write amplifier circuit.

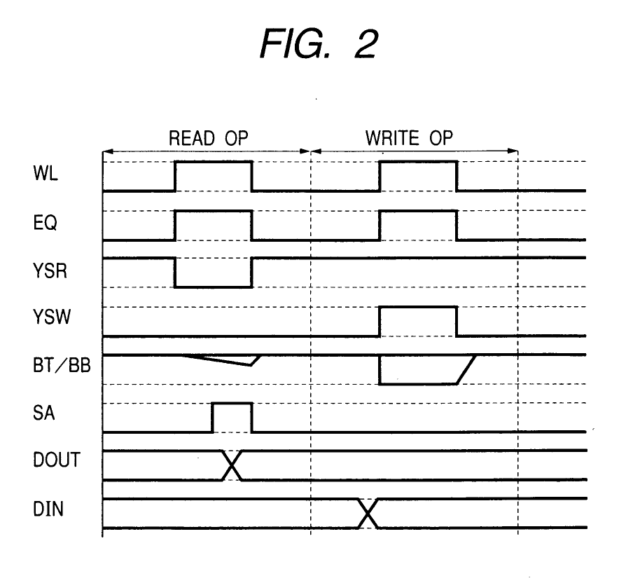

Now, read and write operations are described below by reference to operating waveforms shown in FIG. 2. In FIG. 2, the first cycle indicates a read operation (READ OP) and the second cycle indicates a write operation (WRITE OP) In read operation,after an address or a clock is inputted, it is decoded by the decoder circuit in the control circuit 13, and based on the result, a word line WL is selected. At the same time, the level of the pre-charge/equalize signal EQ rises from “L” (“LOW” level) to “H” (“HIGH” level and the read Y switch control signal YSR drops from “H” to “L”. This generates an extreme small voltage difference between the bit lines (BT,BB) and the voltage difference could be amplified by activating the sense amplifier circuit(107,108) by the control signal SA and data could be sent to the data input and output circuit (10), and the read data appears at an external output DOUT through the output buffer.

In write operation, after an address or a c lock is inputted, it is decoded by the decoder circuit of the control circuit 115, and based on the result, a word line WL is selected. At the same time, the level of the pre-charge/equalize signal EQ rises from “L” (“LOW” level) to “H” (“HIGH” level and the read Y switch control signal YSW drops from “L” to “H”. At the-same time, data from an external input DIN is sent out onto the bit lines (BT,BT) through the input buffer circuit and the write amplifier circuit and then written into the memory cells.

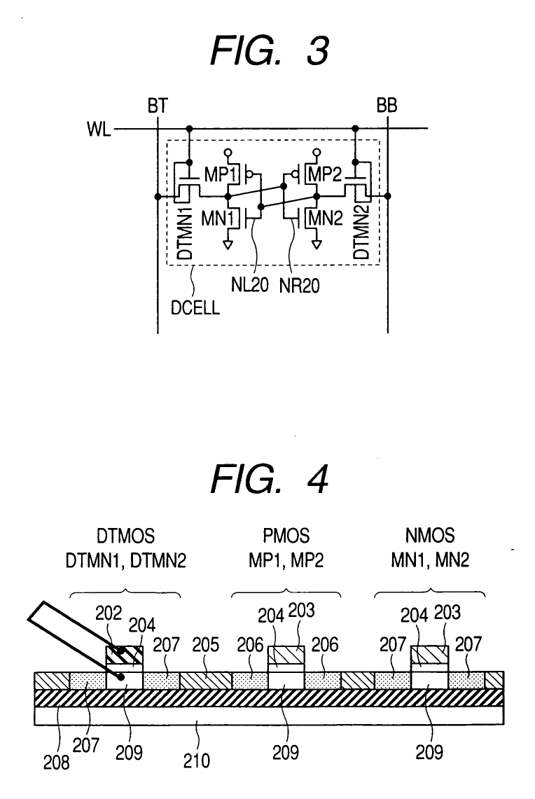

FIG. 3 is a view of one of a plurality of static-type memory cells in the memory array 111 shown in FIG. 1, and is formed on the SOI base substrate. FIG. 4 is a schematic view showing the cross-sections of the elements (MP1, MP2, MN1, MN2, DTMN1, and DTMN2) used in FIG. 3.

The memory cell (DCELL) is made up of; a flip-flop (consisting of the load P-channel type MISFET (MP1,MP2) and the drive N-channel type MISFET (MN1,MN2)) having a pair of CMOS inverters of which inputs and outputs are connected to each other, and transfer N-channel type MISFETs (DTMN1,DTMN2) for selectively connecting the storage nodes NL20 and NR20 of the flip-flop to the bit lines (BT,BB). The SOI, as shown in FIG. 4, an insulating layer (208) is deposited between the first single crystal silicon layer and the second single crystal silicon layer (210), where in the first single crystal silicon layer, the region forming the channel (209) and diffusion layers (207,206) of the MISFET are formed. N-type dopants are implanted into the diffusion layer (207) and P-type dopants are implanted into the diffusion layer (206). The regions (209), in which the channels for P-channel type MISFET (MP1,MP2) and the channels for N-channel type (MN1,MN2) are formed, are not coupled to a wiring line supplying voltage and are in a floating state, while the regions (209), in which the channels for MISFET (DTMN1,DTMN2), are coupled to a wiring line supplying voltage and their potentials are controlled. When elements are formed on a SOI, as shown in FIG. 4, the elements are separately formed and the potentials of the regions, forming the elements are generally not controlled, in a floating state. The same conductivity type elements are formed in the common well if formed on a bulk, where the P-channel type MISFET is formed, the well potential is controlled by a power potential VDD, the highest operating voltage and where the N-channel type MISFET is formed, the well potential is controlled by a ground potential VSS, the lowest operating voltage potential. On the other hand, if formed on a SOI where the elements are separately formed, the potentials of the regions forming the elements, are difficult to control separately due its limited space. Moreover, while the element formation region of the elements in the memory cell in a floating state, will allow noise to easily propagate to the memory cell of non-selected word lines, and which are connected to the driven bit lines. To avoid this problem, the wiring line supplying a voltage is coupled to the regions, in which the channels for the N-channel type MISFETs (DTMN1, DTMN2) are formed, and at least feed a low voltage, such as a ground potential, to the memory cells connected to the non-selected word lines.

It is possible to supply to the wiring line a fixed voltage of the lowest operating voltage of the circuit, (0 V)while the word line is being or not being selected, but as shown in FIG. 4, it is useful to couple the gate electrodes of the N-channel type DTMISFETs (DTMN1,DTMN2) to the channel regions, respectively. The MISFET, of which gate and channel region is coupled, is called a DT (Dynamic Threshold) MOS and has such a characteristic that it is capable of varying its threshold voltage dynamically, enabling the potential responsive to the voltage applied to the word line WL to be supplied to the channel formation regions of the N-channel type DTMISFETs (DTMN1,DTMN2). When not being selected, the N-channel type DTMISFETs (DTMN1,DTMN2)connected to the word line are always on an off state, wherein a low potential (ground potential) is supplied to the channels and the channel region is not on a floating state, reducing leakage current. On the other hand, when being selected, the potentials of the channels go “H” and their threshold voltages drops, thereby the memory cell current increases, enabling high-speed operation. Besides, by removing portion of a gate insulating film to conduct the channel formation regions of the N-channel type MISFETs (MN1,MN2) to the wirings of the gate electrodes, such another advantage may be enjoyed that the devices can be manufactured more easily than by connecting the channel formation region of the N-channel type MISFET (MN1,MN2) to the fixed power wiring line (ground line).

In this embodiment, the source-drain regions of the P-channel type MISFETs (MP1,MP2) are formed in the first silicon layer, and the source-drain path, which the current flows is formed in horizontal direction against the substrate, which forms a lateral MISFET. But alternatively, a vertical MISFET having the source, the channel region, and the drain formed on a laminated base extending in the vertical direction against the principal face of the semiconductor substrate, and the gate electrode formed on the side wall of the laminated base having a gate insulating film in between may be used. The vertical MISFET used as a load is formed above the transfer and drive N-type MISFETs, which is formed in the SOI substrate for connection. By forming the P-channel type MISFETs above the SOI substrate, the space requirement of the memory array can be reduced. The channel region of the vertical MISFETs are also in a floating state with no connection to the wiring line supplying a potential. The channel formation region and the gate electrode are not connected, thereby such limitations can be eliminated that in the case of they are being connected, leakage current is forcibly to increase and the operating voltages between the source and the drain of the P-channel type MISFETs (MP1,MP2) must be controlled below the potential of a diode.

Similarly, for the N-channel MISFETs (MN1, MN2), the channel formation region and the gate electrode are not connected with that region in a floating state, thereby such limitations can be eliminated that in the case of they are being connected, leakage current is forcibly to increase and the operating voltages between the source and the drain of the N-channel type MISFETs (MN1, MN2) must be controlled below the potential of a diode.

Second Embodiment

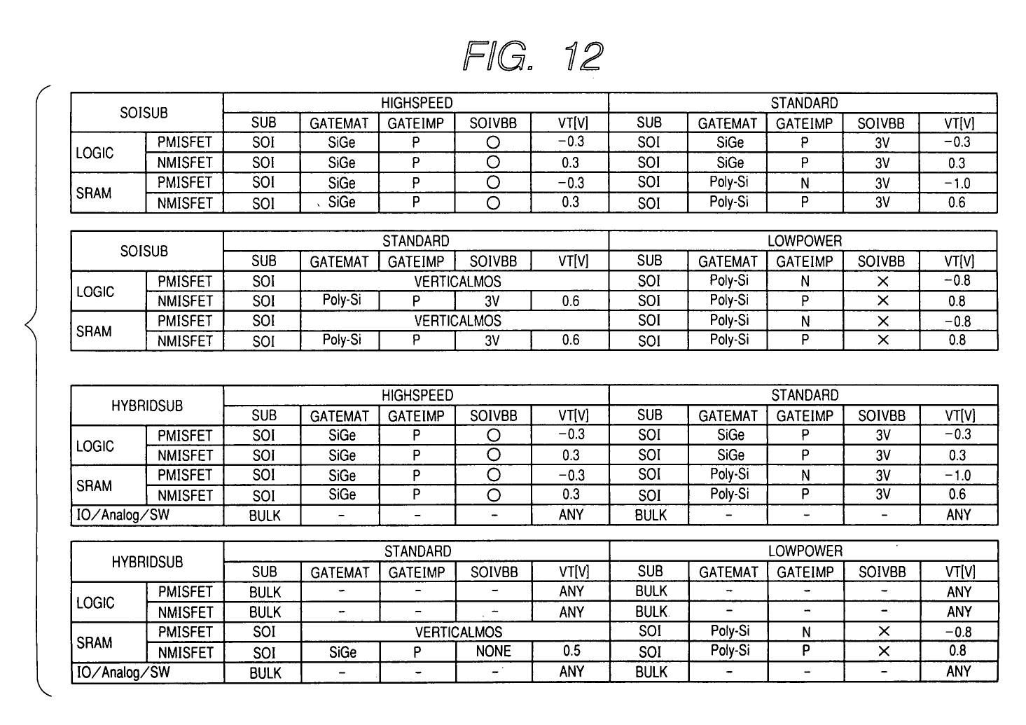

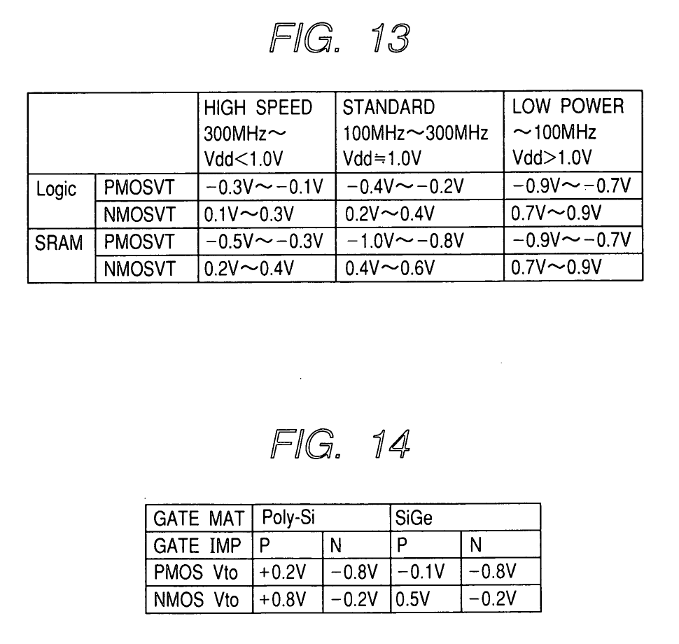

In the first embodiment, one example of a solution for the problems, which arise when the element formation region of the SRAM memory cells formed in a SOI is in a floating state, has been explained. In this embodiment, one example of a solution for the problem of setting the threshold voltages for especially the Full Depletion-type SOI (FDSOI) is described. As shown in FIG. 13, a future semiconductor device mounting SRAM memory cells, especially SRAMs (HIGH SPEED) which require 300 MHz or more high speed operation, needs about −0.5 to −0.3 V for P-type MISFET threshold voltage VT and about 0.2 to 0.4 V for N-type MISFET threshold voltage VT in the memory cell portion, and about −0.3 to −0.1 V for P-type MISFET threshold voltage VT and about 0.1 to 0.3 V for N-type MISFET threshold voltage VT in the logic portion, respectively. Standard SRAMs of 100 MHz to 300 MHz operation(STANDARD) requires about −0.1 to −0.8 V for P-type MISFET threshold voltage VT and about −0.4 to −0.6 V for N-type MISFET threshold voltage VT in the memory portion, and about −0.4 to −0.2 V for P-type MISFET threshold voltage VT and about 0.2 to 0.4 V for N-type MISFET threshold voltage VT in the logic portion, respectively. 100 MHz or lower SRAMs which low power is required (LOW POWER), needs about −0.9 to −0.7 V for P-type MISFET threshold voltage VT and about 0.7 to 0.9 V for N-type MISFET threshold voltage in both memory cell and logic portions,. To reduce leakage current enhancement type MISFETs are required, which no current flows when 0 V potential is supplied between the gate and the source. The device is designed so that in the logic portion, the absolute value for the P-type MISFET threshold voltage may be equal to that for the N-type MISFETs and in the SRAM memory cell portion, the absolute value for the P-type MISFET threshold voltage may be equal to or larger than that for the N-type MISFETs to enhance the driving performance of the N-type MISFETS, and minimize leakage current with the P-type MISFETs. After then, the threshold voltages are desirably set to a relatively high value for a low power-type SRAM (LOWPOWER), to a relatively low value for a high speed-type SRAM (HIGHSPEED), to different values for the P-type MISFET and the N-type MISFET for a standard-type MISFET (STANDARD) because importance is given to the balance between low-power performance and high-speed performance. On the other hand, as shown in FIG. 14, the P channel-type MISFETs having the gate electrodes formed of polysilicon which have P-type dopants implanted and the N channel-type MISFETs having the gate electrodes formed of polysilicon which have N-type dopants implanted, which are commonly used, cannot produce MISFETs with threshold voltages necessary for an operatable device. To solve this problem, the inventors of the present invention have tested and as a result achieved the desired threshold voltages in the SRAM memory cell portion (SRAM) and the logic portion (LOGIC) by successfully combining such parameters listed in FIG. 12 as the type of substrate (SUB) the gate material (GATEMAT), the conductivity type of the dopants implanted into the gate electrode (GATEIMP), and the application of a substrate bias onto the SOI base substrate (SOIVBB). The method for setting the threshold voltages for the SOI substrate (SOISUB) having only a SOI base substrate (SOI) with no bulk part (BULK) is described in the upper part, while that for the hybrid substrate (HYBRIDSUB) having both the SOI base substrate (SOI) and the bulk part (BULK) is described in the lower part. If it has a bulk portion, the gate material (GATEMAT) and the conductivity type (GATEIMP) of the dopants implanted into the gate electrode can be selected without a restriction, and any threshold voltages can be fabricated, since the threshold voltages can be controlled by adjusting the quantity of the dopants implanted into the channel region. In the table, “P” for the conductivity type (GATEIMP) of the dopants implanted into the gate electrode indicates that ions such as boron fluoride (BF₂) have been implanted as P-type impurities and “N” for the conductivity type indicates that ions such as phosphor (P), arsenic (As) have been implanted as N-type impurities. “VERTICALMOS” indicates that a vertical MISFET described in the first embodiment has been used to reduce the space requirement and the number of threshold voltages required on the SOI, improving the freedom of design.

In this embodiment, the method is described for fabricating a MISFET having a threshold voltage suitable for a LSI mounting SRAM memory cells on a hybrid substrate having both the SOI portion and the bulk portion. Compared with a SOI substrate with no bulk part, its manufacturing process is complicated but higher stability of operation can be ensured. Note that in this semiconductor device, it is very useful to combine the SRAM, with which problem of floating described in the first embodiment has been solved, and to combine the embodiments described after this embodiment.

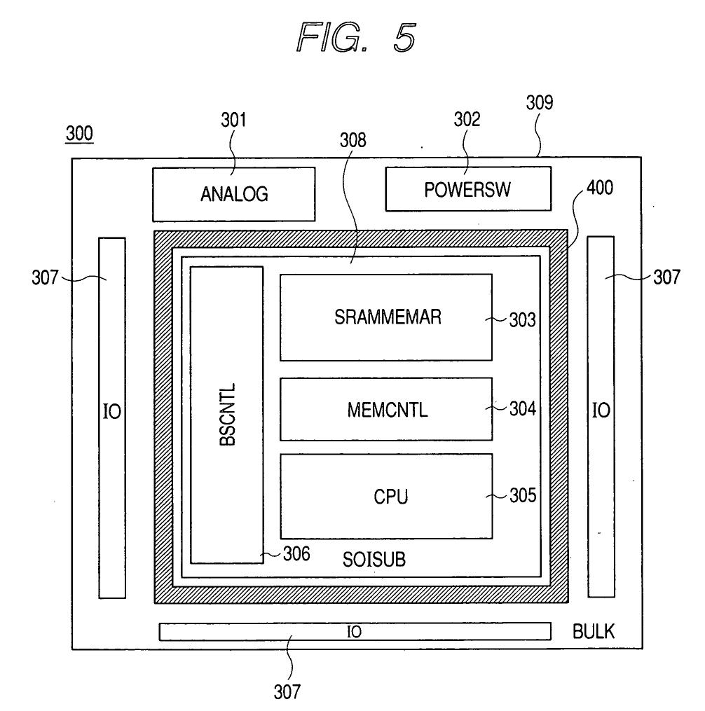

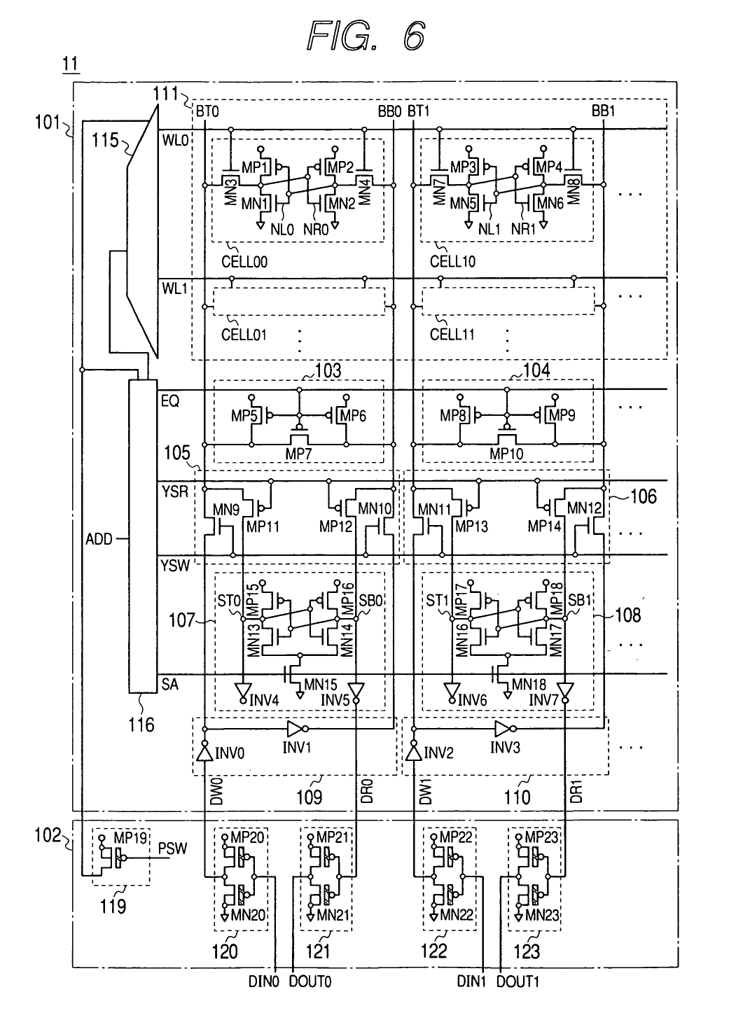

FIG. 5 is a block diagram of a semiconductor device 300 using a hybrid substrate. On the Full Depletion type of SOI base substrate 308, a SRAM memory array 303, a memory control circuit 304, a CPU circuit 305, and a bus control circuit 306 are formed. In the bulk silicon region 309 which lays outside of the SOI substrate, an analog circuit 301, a power switch circuit 302 controlling operation voltage of circuits such as a memory control circuit, an input and output circuit 307, and a power supply portion 400 for supplying voltage on the SOI base substrate are formed. The power supply part 400 inflicts a substrate bias on the elements formed on the SOI to vary the threshold voltages VTs of the elements. The application of voltage on the SOI base substrate itself eliminates the need for individually controlling over the channel formation regions of the elements. To uniformly inflict a voltage onto the SOI base substrate, the power supply region 400 have been formed around the SOI base substrate in the form of a ring. In other words, they have been formed adjacent to the SOI base substrate in the bulk area. Also, by forming the power supply in the bulk region, it can be formed using the process used to form elements in the bulk portion. The analog circuit 301 has a power circuit having a step-down voltage circuit generating operating voltage of SRAM memory cells, a clock generator circuit(PLL), and the like.

The gate electrodes of the P-channel type MISFETs, which is used in the SRAM memory array 303, the bus control circuit 306, and the paths other than a critical path in the CPU circuit 305 formed in the Full Depletion type of SOI region 308, are formed using N-type polysilicon, while the gate electrodes of the N-channel type MISFETs are formed using P-type polysilicon. The gate electrodes of both of the P-channel type and N-channel type MISFETs, which are used in the memory control circuit 304 and the critical paths in the CPU 305 formed in the Full Depletion type of SOI region, are formed using P-type germanium. In the case that for example, avoltage of 3 V is applied to the silicon substrate under an oxide film embedded in the Full Depletion type SOI region 309, it could be possible to set the threshold voltages of the P-channel type MISFETs to −1.0 V, and the threshold voltages of the N-channel type MISFETs to 0.6 V, which the MISFETs are used in the SRAM memory array 303, the bus control circuit 306, and the paths other than a critical path in the CPU circuit 305, while set the threshold voltages of the P-channel type MISFETs to −0.3 V, and the threshold voltages of the N-channel type MISFETs to 0.3 V, which MISFETs are used in the memory control circuit 304 and the critical paths in the CPU 305.

The analog circuit 301, the power switch circuit 302, and the input and output circuit 307 are formed in the bulk silicon region 309 and their threshold voltages can be set to any value by changing the dose of dopants.

Thus, even if SRAM, peripheral circuits, and logic circuit are formed on SOI, device performance will not deteriorate because optimal threshold voltages can be set for each circuit, allowing to get the benefits of the SOI characteristics. The SRAM cells can operate more stably at a lower operating voltage, and can operate at a higher speed with the same level of leakage current and the resistance against soft errors is improved, compared with SRAM formed on a conventional bulk silicon.

Among semiconductor chips 300 described above, the memory cell array 303, memory cell control circuit 304, the input and output circuit 307, and the power switch 302 used in general use SRAM memories are in detail shown in FIG. 6. A SRAM chip 11 is a component of the semiconductor integrated circuit and is formed on the hybrid semiconductor substrate having both of the Full Depletion type SOI region 101 and the bulk silicon region 102. In FIG. 6, the substrate potentials of the MISFETs formed on the bulk region is connected to Highest potential or Lowest potential of the operating potential of the circuit.

A plurality of SRAM memory cells (CELL00, CELL01, CELL10, and CELL11) are disposed into the form of a matrix, forming a memory array 111. The memory array 111 is formed on the Full Depletion type SOI region 101.

The memory cell CELL00 comprises a flip flop formed by connecting inputs and outputs of a pair of CMOS inverter (having P-channel type MISFETs (MP1, MP2) and N-channel type transistors (MN1, MN2)) and N-channel type MISFETs (MN3, MN4) for selectively connecting a storage nodes NL0 and NR0 of the flip flop to bit lines (BT0, BB0). The word line WL0 is connected to gate electrodes of the N-channel type MISFETs (MN3, MN4).

The memory cell CELL10 comprises a flip flop formed by connecting inputs and outputs of a pair of CMOS inverters (having P-channel type (MP3, MP4) and N-channel type transistors (MN5, MN6)) and N-channel type MISFETs (MN7, MN8) for selectively connecting storage nodes NL1 and NRl of the flip flop to bit lines (BT1, BBl). The word line WL0 is connected to gate electrodes of N-channel type MISFETs (MN7, MN8). The use of memory cells (DCELL) used in the embodiment can suppress noise transmitted to a non-selected word line.

The column circuit comprising sense amplifier circuits (107, 108), write amp circuits (109, 110), recharge equalize circuits (103, 104), and Y switch circuits (105, 106) is disposed in a column.

The control circuit 116 controlling control signals (SA,YSW,YSR,EQ) and the word decoder driver circuit 115 decoding word lines (WL0,WL1) are also included. All of these circuits are formed on a SOI substrate 101.

The power line VDDI supplying operating voltage of the control circuit 116 and the word decoder driver circuit 115 is connected to a power potential VDD through a power switch 119. The power switch 119 is made using a P-channel type MISFET 19 and to gate electrode of the MISFET 19, a control signal line PSW is connected. The power switch 119 controls voltage applied to the memory control circuit and the like. Alternatively, instead of the P-channel type MISFET, the N-channel type MISFET connected to a ground potential VSS, or both P-channel type and N-channel type MISFETs may be disposed between the ground potential VSS and the power line.

The input circuit 120, which drives an external write data DIN0 to input as DW0 to the write amplifier 109, is made up of a P-channel type MISFETMP 20 and an N-channel type MISFETMN 20.

The input circuit 122, which drives an external write data DIN1 to input as DW1 to the write amplifier 110, is made up of a P-channel type MISFETMP 22 and an N-channel type MISFETMN 22.

The output circuit 121, which drives an output signal DRO from the sense amplifier circuit to output to an external device as DOUT0, is made up of a P-channel type MISFETMP 21 and an N-channel type MISFETMN 21.

The output circuit 123, which drives an output signal DR1 from the sense amplifier circuit to output to an external device as DOUT1, is made up of a P-channel type MISFETMP 23 and an N-channel type MISFETMN 23.

The power switch circuit 119, the input circuits (120,122), and the output circuits (121,123) are formed in the bulk silicon region 102.

Read and write operations are performed in the same manner as those shown in the first embodiment.

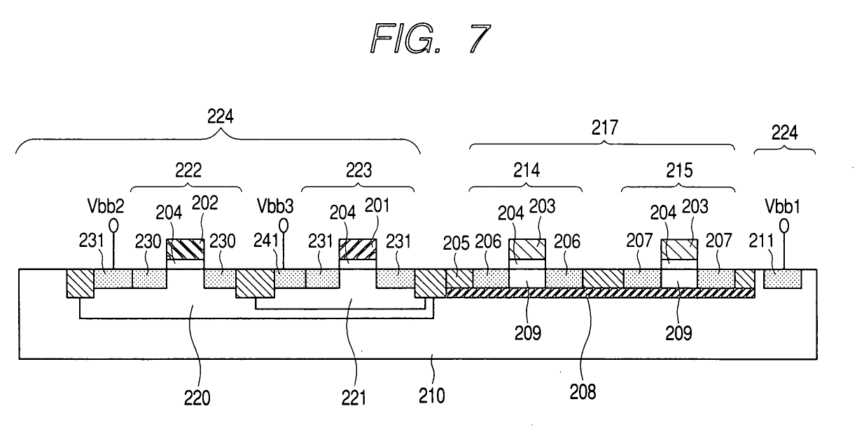

FIG. 7 is a schematic view of the cross section of the element used in this embodiment. A semiconductor substrate 210 has a Full Depletion type SOI region 217 and a bulk silicon region 224. By the SIMOX (Separation By Implanted Oxygen) method, an embedded insulating film under a element formation region of a SOI base substrate is formed in a portion of the substrate by partially injecting oxygen, thereby as shown in FIG. 7, with the heights of surface in the bulk portion 224 and in the SOI portion 217 being the same, and gate insulating films 204 of the MISFETs and the like in the bulk portion and in the SOI portion can be manufactured by the same process. Note that this method requires the determination of the regions of the SOI and bulk portions by the process of oxygen injection. On the other hand, if the first and second semiconductor layers are bonded together having an insulating film in between into a SOI substrate (Wafer Bonding), the bulk portion in formed by etching a portion of the first semiconductor layer and the insulating film to removed and elements are formed on the exposed surface of the second semiconductor substrate. For this reason, the heights of the surfaces of the SOI and bulk portions are different, making it hard to manufacture the gate insulating films 204 and the like by the same process. In contrast, the etching step separates the bulk portion and the SOI portion, giving such an effect that the SOI substrate has higher versatility.

In the SOI region 217, the diffusion layers 206 and 207 of a N-channel type MISFET 215 and a P-channel type MISFET 214 are formed in the silicon layer above the embedded oxide film 208 and the MISFETs formed on the SOI base substrate portion by a film oxide 205, even though they are of the same conductivity type, are separated one another. In a bulk silicon region, a power supply region 211, which has an impurity density higher than and the same conductivity type as that of the semiconductor substrate 210, and a P-type well semiconductor region 220 forming a PN junction with the semiconductor substrate are formed. In the P-type semiconductor region 220, a N-type well semiconductor region 221 forming a PN junction with the P-type semiconductor region 220 is formed. In the P-type semiconductor region 220, a power supply part 231, which has an impurity density higher than and the same conductivity type as that of the P-type semiconductor region 220, and is fed by a potential Vbb2 (low operating voltage of the circuits, ground potential), and a N-type diffusion layer 230 of the N-channel MISFET 222 forming a PN junction with the P-type semiconductor region 220 are formed. In the N-type semiconductor region 221, a power supply part 241, which has an impurity density higher than and the same conductivity type as that of the N-type semiconductor region 221 , and is fed by a potential Vbb3 (high operating voltage of the circuits) to the semiconductor region, and a P-type diffusion layer 231 of a P-channel type MISFET 223 forming a PN junction with the N-semiconductor region are formed. Using this configuration, the threshold voltages of the MISFET elements formed on the SOI base substrate can be varied easily. To vary the threshold voltages of the MISFETs formed on the SOI base substrate by applying voltage on the base substrate, a voltage larger (for example, 3 V) than the operating voltage of the circuits formed in the bulk layer need to be applied. To solve such a problem that voltage is difficult to control, single power source is used to easily control voltage and the power region 221 is formed in the bulk region in this embodiment. When a negative voltage is applied to Vbb1, the conductivity type is the reverse of that mentioned above and the commonly used P-type semiconductor substrate can be used for semiconductor substrate 210. Since a negative voltage is difficult to generate, in this embodiment an N-type substrate is used for substrate 210 and positive voltage is inflicted. Since this voltage is larger than that applied to internal circuits, using a voltage inputted externally from the semiconductor chip directly for the power region and inputting the voltage to the power circuits such as the step-down voltage circuit to apply the output voltage for internal circuits is useful. Note that the use of an N-type semiconductor substrate 210 avoids the generation of parasitic diode between the wells in the bulk portion, suppressing leakage current. In case that a P-type semiconductor substrate is used, about 3 V of voltage is applied to Vbb1, and the well potential of the N-type semiconductor region 220 is set to about 1 V, the highest potential applied to the circuits, a diode is generated between the substrate 210 and the N-type semiconductor region 220, causing the circuit elements to stop operation. In this case, if the well potential is set to about 3 V, no diode is formed, though a substrate bias is applied to the elements in the wells. This may increase the threshold voltages and induce GIDL current.

The power supply part 211 for applying voltage onto the SOI base substrate is formed into a ring surrounding the SOI portion to apply voltage uniformly onto the base substrate.

On the bulk silicon substrate, the N-channel type MISFET 222 and P-channel type MISFET 223 are formed.

In the Full Depletion type SOI region 217, a memory cells CELL and sense amplifier circuits (107, 108), write amplifier circuits (109,110), precharge/equalize circuits (103,104), Y switch control circuits (105,106), a control circuit 116, and a word decoder/driver circuit 115 are formed. In the bulk silicon region 224, the power switch circuit 119 and input circuits (120,122), and output circuits (121,123) are formed. The power switch circuit 119 may be laid in the vicinity of the circuits, of which operating voltages are controlled to improve the response of the switch, though it is in a floating state, if being formed on the SOI substrate, and it is difficult to suppress leakage current in the circuits. To solve this problem, the power switch parts of individual circuits are formed together in the portion of the bulk substrate.

The P-channel type MISFET 214 has a channel region 209, source-drain formed by P-type diffusion layer 206, a gate oxide film 204, and a gate electrode formed by silicon germanium 203 with P-type dopants implanted. The N-channel type MISFET 215 has a channel region 209, source-drain formed by N-type diffusion layer 206, a gate oxide film 204, and a gate electrode formed by silicon germanium 203 with P-type dopants implanted. The P-channel type MISFET 223 has a N well region 221, source-drain formed by P-type diffusion layer 235, a gate oxide film 204, and a gate electrode 202. The N-channel type MISFET 222 has a P well region 220, source-drain formed by N-type diffusion layer 230, a gate oxide film 204, and a gate electrode 202.

Since the P-channel type MISFET 223 and the N-channel type MISFET 222 are formed on the bulk substrate, the threshold voltages can be optionally set by adjusting the concentration of dopants implanted into the diffusion layers and the conductivity type of the dopants injected into the gate electrode and the gate electrode materials is not limited. To streamline the manufacturing steps, it is useful that like the MISFETs formed on the SOI, silicon germanium is used for the gate electrode and according to the characteristic profile, P-type dopants is implanted into the gate electrodes of the P-channel type MISFETs and N-type dopants is implanted into that of the N-channel type MISFETs.

By applying voltage (about 3 V) from a terminal of the power supply region 211 formed in the bulk portion of the silicon substrate 210, the threshold voltages of the P-channel type MISFETs formed in the Full Depletion type SOI region 217 can be made to −0.3 V and the threshold voltages of the N-channel type MISFETs to 0.3 V, respectively. In the bulk silicon region., the threshold voltages are not varied by the voltage applied by Vbbl, if a power potential, for example 1 v of voltage, is applied to the well power supply part 241 to fix the potential of the N well region 221 and a ground potential, for example 0 V of voltage, is applied to the well power supply part 231 to fix the potential of the P well region 220.

By applying this, the threshold voltages of the peripheral circuits and memory cells could be set low allowing high speed operation, and the threshold voltages of the power switch could be set high enabling the standby current to reduce.

Thus, by forming SRAM and it peripheral circuits on the SOI and bulk silicon hybrid substrates and setting the threshold voltages suitable for each circuit, the SOI characteristics can be fully used with no deterioration in performance. Compared with SRAM formed on the conventional bulk silicon, the SRAM cells of the present invention can operate stably at a lower voltage, operate at a higher speed with same level of leakage current, and improve its resistance to soft errors.

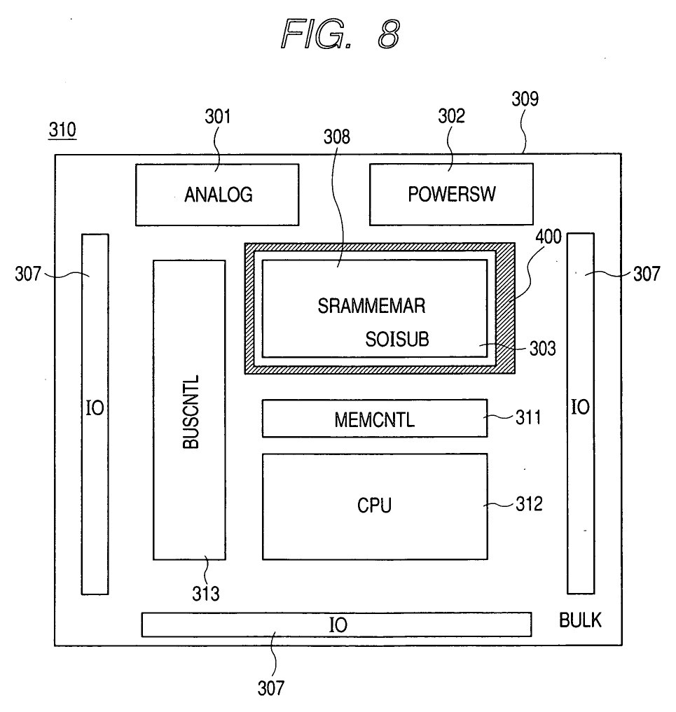

FIG. 8 is a variation in which the SOI substrate 308 is used only for the SRAM array memory array 303. For the logic portion to operate at a high speed, it is preferable that a memory control circuit 311, a bus control circuit 313, and CPU312 are formed on the SOI base substrate. On the other hand, to form two types of threshold voltages, the gate electrode material must be changed, making the manufacturing process complicated. To solve this problem, according to this variation, the memory control circuit 311, the bus control circuit 313, CPU312, a power supply part 400 for applying voltage into the SOI base substrate is formed in the bulk, and the quantity of the dopants injected into the diffusion layers is adjusted to optionally set the threshold voltages. According to this variation, the power supply part 400 for applying voltage the base substrate is formed in shape of a ring surrounding the memory cell array 303.

Third Embodiment

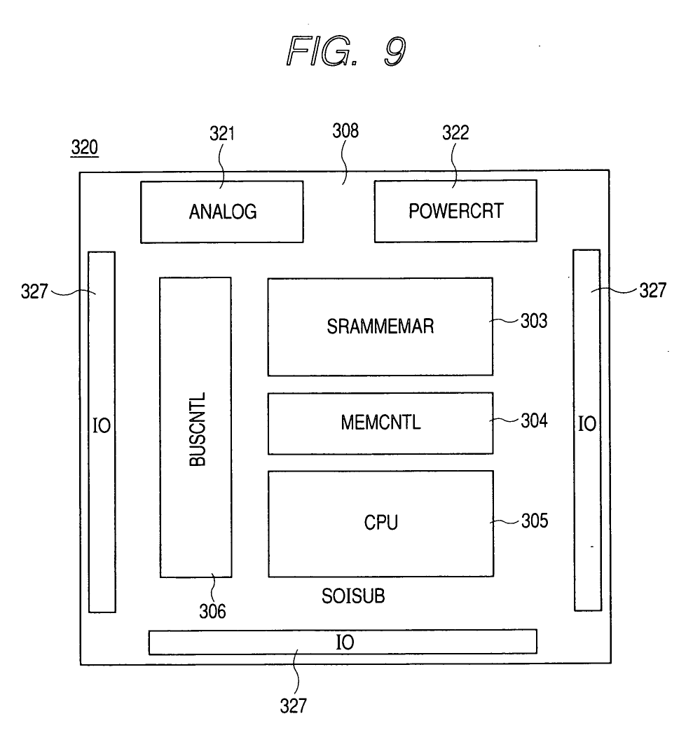

In this embodiment, the method for realizing a semiconductor device mounting SRAM memory cells using the SOI substrate with no bulk portion, instead of the hybrid substrate, is described. This method allows the manufacturing process simple compared with the hybrid substrate. FIG. 9 is a view, in which all the circuits configured in the block diagram shown in FIG. 8 are formed on the SOI substrate 308.

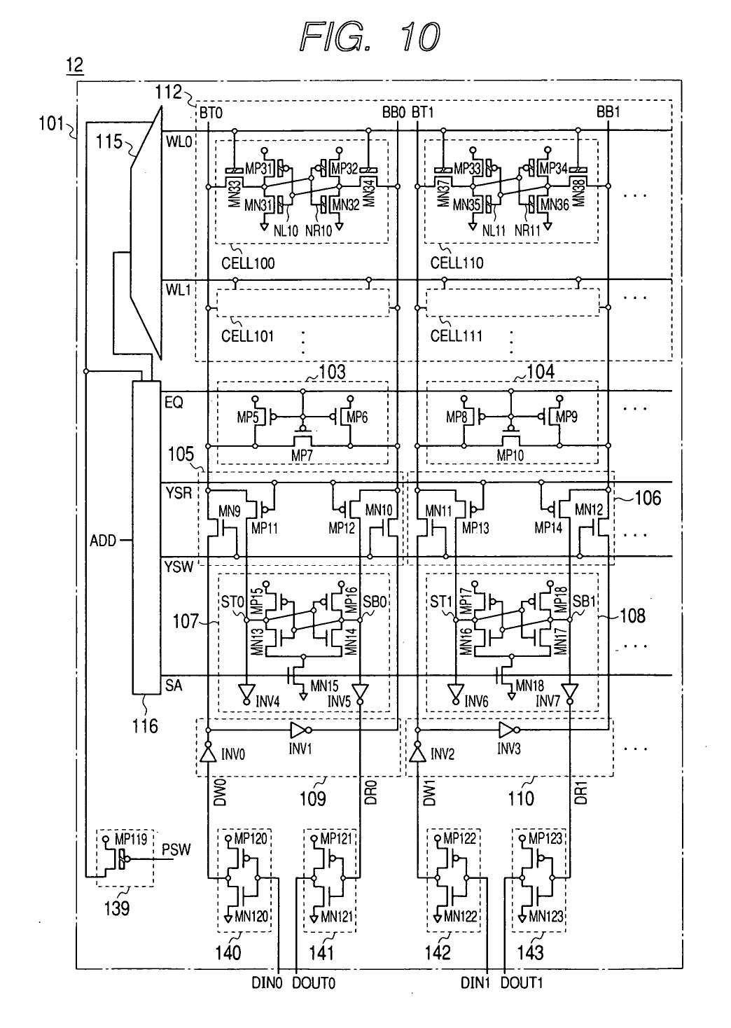

FIG. 10 shows the semiconductor chips 302, especially the memory array 303, the memory control circuit 304, the input and output circuit 307, and the power switch circuit 302 in detail. The SRAM chip 12, a semiconductor device, is a part of the semiconductor integrated circuit, and is formed on the semiconductor substrate such as the Full Depletion type SOI substrate 101. The circuit configuration is the same as that shown in FIG. 6 of the second embodiment with such an exception that different types of MISFETs are used. The read and write operations are the same as those of the first embodiment. In FIG. 10, the gate electrodes described with thick gate parts of the MISFETs are made of polysilicon and the gate electrodes described with thin gate parts of the MISFETs are made of silicon germanium.

The gate electrodes of the P-channel MISFETs (MP31 to 34) are made of N-type polysilicon and the gate electrodes of the N-channel type MISFETs (MN31 to 38) composing the memory cell CELL are made of P-type polysilicon. In addition, the gate electrode of the P-channel MISFET (MP119) composing the power switch is made of N-type polysilicon. In other circuits, the gate electrode of the P-channel type MISFETs and N-channel type MISFETs is made of P-type silicon germanium.

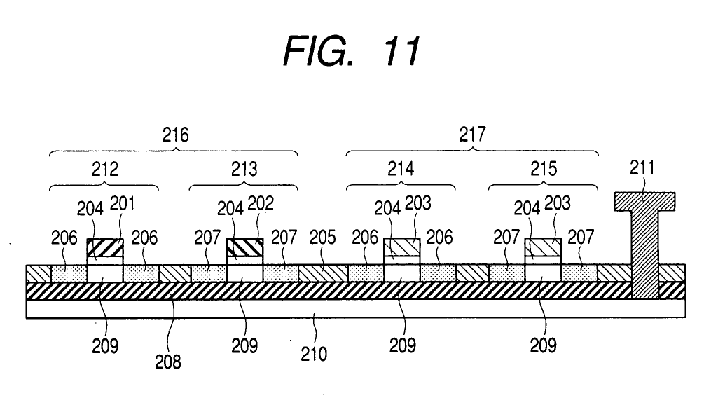

FIG. 11 is a schematic view of the cross section of the MISFET used in this embodiment. The MISFETs are formed in the silicon layer above the embedded oxide film 208, which is above the silicon substrate 210 and the elements are separated by the field oxide film 205 each other. The region 216, in which the SRAM memory cells CELL and the power switch 139 are formed, includes the P-channel type MISFET 212 and N-channel type MISFET 213. The region 217, in which the circuits other than the SRAM memory cells CELL (the circuits having the MISFETs of which gate parts are thinly represented in FIG. 10), includes the P-channel type MISFET 214 and the N-channel type MISFET 215.

The P-channel type MISFET 212 has a channel region 209, source-drain formed by P-type diffusion layer 206, a gate oxide film 204, and a gate electrode formed by N type polysilicon 201. The N-channel type MISFET 213 has a channel region 209, source-drain formed by N-type diffusion layer 207, a gate oxide film 204, and a gate electrode formed by P type polysilicon 202. The P-channel type MISFET 214 has a channel region 209, source-drain formed by P-type diffusion layer 206, a gate oxide film 204, and a gate electrode formed by P type silicon germanium 203. The N-channel type MISFET 215 has a channel region 209, source-drain formed by N-type diffusion layer 207, a gate oxide film 204, and a gate electrode formed by P type silicon germanium 203.

By applying a voltage (for example 3 V) onto the silicon substrate 210 from the power terminal 211, the threshold voltages of the P-channel type MISFET and the N-channel type MISFET formed in the region 216 can be set to −1.0 V and 0.6 V, respectively and the threshold voltages of the P-channel type MISFET and the N-channel type MISFET formed in the region 217 can be set to −0.3 V and 0.3 V, respectively. Note that in the case that power is supplied from the side of the surface of the substrate, on which the element region is formed, voltage transfer between the circuits formed on the SOI substrate and applied voltage can be performed and the use of packages, in which pads can be formed only on one side, such as BGA(Ball Grid Array), facilitates manufacturing. In the case of packages with lead frames are used, voltage can be applied directly from the rear side, applying voltage from external to the chip.

For this reason, since the threshold voltages of the peripheral circuits are low, the circuits can operate at a high speed and since the threshold voltages of the memory cells CELL are high, a leakage current can be reduced for data retaining. Since the threshold voltages of the power switch MP119 are high, a leakage current can be reduced and reduce the standby current.

Fourth Embodiment

In the embodiment given above, such a method for controlling static threshold voltages has been described that substrate bias voltage is applied onto the SOI substrate. In this embodiment, such a method for controlling dynamic threshold voltages of transistors on the SOI substrate is described that they are varied depending on their operating status.

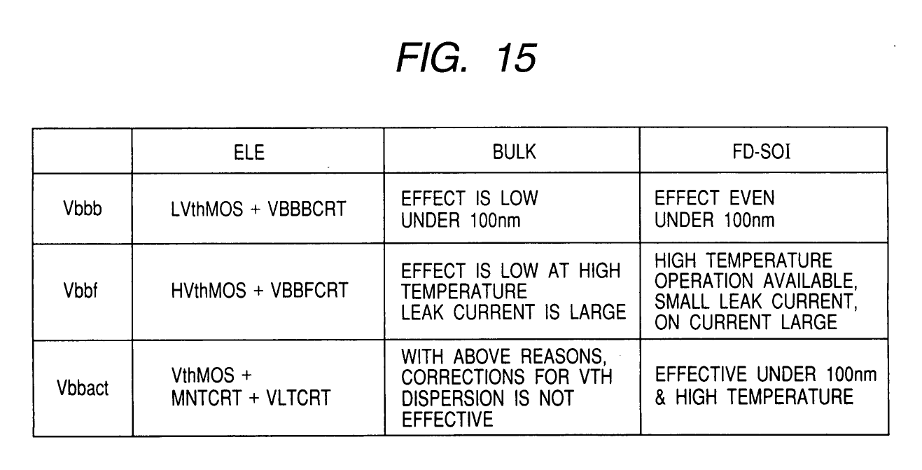

FIG. 15 is the explanation of the configuration (ELE) and the effect in the case that substrate bias voltage is applied on the SOI substrate to control the threshold voltages dynamically.

The back bias (Vbbb) is a technique that applies onto the substrate a voltage lower than that of the source potential for the N-channel type transistors and applies onto the substrate a voltage higher than that of the source potential for the P-channel type transistors to increase the threshold voltage (Vth) of the transistors. This technique, generally, uses a combination of the circuits using the transistors (LVthMOS) with low Vths and the control circuit (VBBBCRT), which increases these threshold voltages when a given condition is met(For example, when the circuit is in a low power mode). This technique achieves high-speed operation with transistors with low Vth and reduces the sub thresholds leakage current by raising Vth when a back bias is applied, suppressing power consumption. But when back bias is applied to the transistors formed on the bulk (BULK) with a gate length of 100 nm or lower, GIDL or a leakage current flowing from the drain to the substrate called a junction leakage increases. For this reason, even though back bias is applied to increase Vth for reducing the subthreshold leakage, it is difficult to reduce the total leakage current. The transistors formed on the SOI substrate, will not case current to flow between the drain and the substrate, because of an insulating film laid between them. This enables transistor of a gate length of 100nm or lower to have both of the advantages that low Vth transistor for high speed operation and minimized leakage current by applying back bias.

The forward bias (Vbbf) is a technique that applies onto the substrate a voltage higher than that of the source potential for N-channel type transistors and onto the substrate a voltage lower than that of the source potential for P-channel type transistors to lower the Vths of the transistors. This technique, generally, uses a combination of the circuits using the transistors (HVthMOS) with high Vth and the control circuit (VBBFCRT), which decreases these threshold voltages when a given condition (For example, when the circuit is in a high-speed operation mode) is met. This technique achieves reduces leakage current and keeps low power consumption by using high Vth transistors and high-speed operation leakage current by decreasing Vth when a forward bias is applied. But, when forward bias is applied to the transistors formed on the bulk substrate (BULK) with a gate length of 100 nm or lower, a forward current flows through the PN junction and the leakage current dramatically increases during device operation, leading to an increase in operating power. In particular, during operation at a high-temperature, the leakage current increases. For the transistors formed on the SOI, an insulating film are laid between the drain and the substrate and between the source and the substrate, causing no current to flow between the drain and the substrate. For this reason, both advantages can be achieved that the use of high Vth transistors minimizes power consumption and the application of forward bias enables the circuits to operate at a higher speed. In addition, a sufficient level of On current, which is an intrinsic merit of-forward bias can be achieved, allowing circuit operation at a high temperature.

The active Vbb(Vbbact) is a technique that uses the back bias and forward bias according to the condition and corrects the variation caused by circuit process and variation in characteristic due to the temperature, enabling circuit operation with high performance. This technique, generally, uses a combination of a circuit composing transistors with any threshold voltages, a monitor circuit for detecting the threshold voltages of these transistors, and a power circuit for varying the threshold voltages of the transistors depending on the detected result and the desired operation mode. For the transistors formed on the bulk (BULK) with a gate length of 100 nm or lower, both of techniques, back bias and forward bias have problems, respectively, which causes problems when Active Vbb technique is used. For the transistors formed on the SOI, the problems involved with the techniques back bias and forward bias are solved and the Active Vbb technique can be effectively applied.

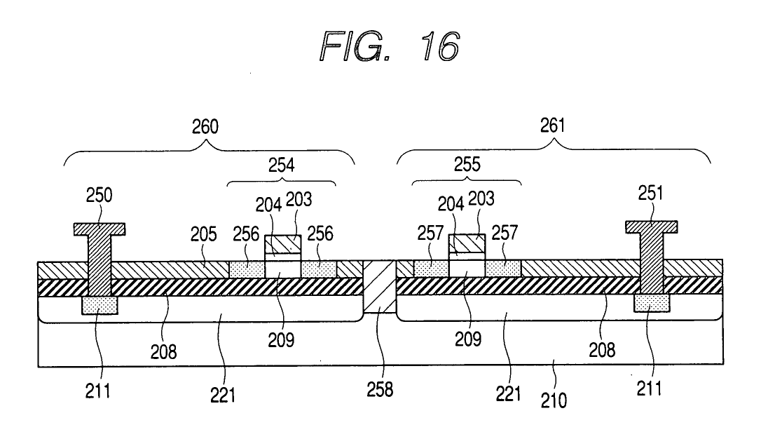

Now, the configuration of the transistors formed on the SOI, of which the threshold voltages are dynamically controlled (Active, Vbb, Back bias) is described. To dynamically control the threshold voltages by applying voltage onto the SOI substrate, the SOI base substrate must be separate into the regions to apply different voltages. The circuit blocks must be separated by each other, each circuit block having the same level of voltage applied to the transistors integrated, and a power supply region must be formed for each block. The cross section of the configuration is shown in FIG. 16. In the semiconductor substrate 210, a plurality of wells 221 are formed, each of which a plurality of SOI transistors are formed of a block. If positive voltage is applied onto the SOI base substrate, using N-type wells in the P-type substrate can simplify the well structure. The first circuit block 260 and the second circuit block 261 can be separated through an insulating region 258 to control the wells individually.

In the first block 260, a plurality of MISFETs 254 are formed, which apply a common first voltage to the SOI base substrate 221. By applying the first voltage (251) to the N-type power supply part 211 having a higher density than the N-type well 221, the channel region 209 of the MISFET formed above can be controlled through the insulating film 208. By changing the first voltage, the threshold voltages of the MISFETs 254 can dynamically change.

In the second block part 261, a plurality of MISFETs 255 are formed, which apply the second voltage (252) to the SOI substrate 221. By applying the second voltage (252) to the N-type power supply part 211 having a higher density than that of the N-type well 221, the channel region 209 of the MISFET formed above can be controlled through the insulating film 208. By changing the second voltage, the threshold voltages of the MISFETs 255 can dynamically change. By separating the SOI base substrate 221, back bias can be applied to one block while forward bias can be applied to another block, enabling the circuits to operate depending on circuit operation status.

The MISFETs in the first and second blocks each have a channel region 209, the source-drain region formed by the diffusion layer 256 and 257, a gate oxide film 203, and a gate electrode 203, and the same materials depending on the requirement may be selected as those used in the previous embodiment.

Fifth Embodiment

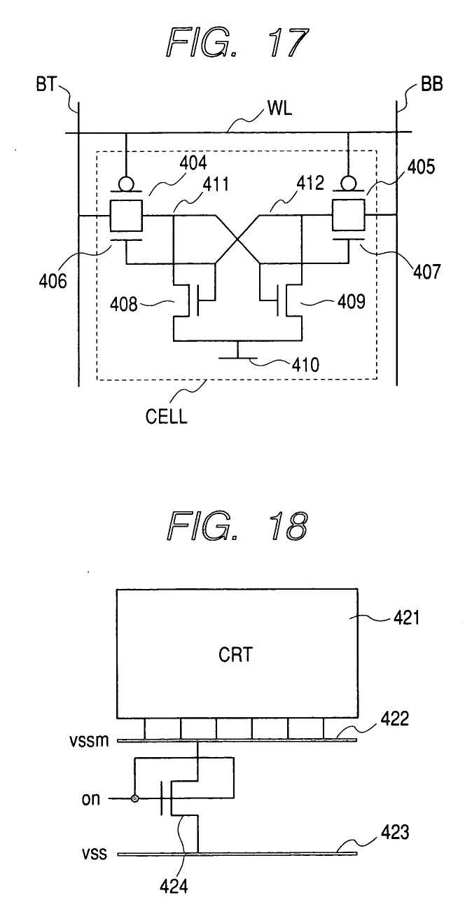

This embodiment, which is a variation of the first embodiment, uses a 4T cell (CELL) composing four transistors as shown in FIG. 17 instead of the memory cells (DCELL) as shown in FIG. 3. Like the memory cells shown in FIG. 3, the memory cells are formed on the Full Depletion type SOI region 101. The memory cell (CELL) connected to the bit lines BT, BB, and the word line WL has P-channel type MISFETs (404,405) and N-channel type MISFETs (408,409). The P-channel type MISFETs (404,405) serve as a load transistor and a transfer transistor. The gates of the P-channel type MISFETs (404,405) are connected to the word line and the source-drain paths are connected between a pair of bit lines and the. drains of N-channel type transistors (408,409). When no write or read operation is performed, to retain information in the memory cell, a high level of voltage is applied to the pair of bit lines (BT, BB) and the P-channel type MISFETs (404,405)serve as load transistors. To use the P-channel type MISFET as a transfer transistor, the write and read operations are performed by applying low voltage onto the selected word line instead of high voltage. The N-channel type transistors (408,409), of which input and outputs are cross-coupled, serve as drive transistors. In this embodiment, in particular, the P-channel type transistors (404,405) have double gate structures, and voltages of store nodes 412 and 411 are applied to the SOI base substrates, on which the P-channel type transistors are each formed. As shown in the transistors (212,213,214,215) in FIG. 11, double gate structures have a control electrode (power supply, 211) on the SOI base substrate, where transistors are formed, and the channels are controlled by two gates on both sides. In this memory cell, the control electrodes (406,407) of two P-channel type transistors (404,405) are individually controlled and therefore are formed on a separate SOI base substrates. This means that the N-channel type transistors of a memory cell can be formed on the same SOI substrate common to other memory cells, though the P-channel type transistors of memory cells must each be separated and even in the memory cell P-channel type transistors have to be controlled by a different SOI base substrate.

4TSRAM memory cells, in which the electrodes of the SOI base substrates are not controlled by the storage nodes, “H” potential must be retained by means of leakage current of the transfer transistor, and therefore leakage current of the transfer transistor connected to the node retaining “L” potential continues to flow regardless of it being unnecessary for operation. This cause such problems that the leakage current of the transfer transistor must be controlled and the leakage current increases more.

Assuming that node 411 connected to the drain electrode of the transistor 404 and the drain electrode of the drive transistor 408 is a node 1, and node 412 connected to the drain electrode of a transfer transistor 405 and the drain electrode of a drive transistor 409 is node 2. The condition in which “L” data is retained in the node 1 and “H” data is retained in the node 2 in the memory cell of the present invention is described. When the memory cell is not accessed, on standby state, the word line is on “H” state and the bit line is on “H” state. The transfer/load transistors, of which word line is connected to the gate electrodes, is on off state. “L” voltage is applied to the electrode 407 on the SOI base substrate side of the P-type transistor 405, of which source-drain path is connected to the node 2 retaining “H” data, putting the transistor into the on state. Accordingly, charges are supplied from the “H” state bit line to the node 2. This retains the node 2 at “H”. The node 1 retaining at “L” state is connected to the drain electrode of the drive transistor 408, which is in on state, being retained at the ground potential, “L”. Since the transistor 404 connected to the node 1 is in off state when being viewed from both gates, no leakage current is necessary for operatation.

Thus, for the SRAM memory cell, of which SOI base substrate is controlled depending on the states of the storage nodes and use double gate type FD-SOI transistors, no leakage current flow is required for operation, thereby the leakage current can be more reduced compared with the conventional 4 transistor-configuration memory cells. Note that the peripheral circuits, except the SRAM memory cell portion, are the same as the memory portion of the SRAM circuits shown in FIG. 1.

In this embodiment, the P-channel type transistors is used for the transfer/load transistors and the N-channel type transistors for the drive transistors and the source electrodes of the drive transistors are connected to a ground potential line. Alternatively, the N-channel transistors may be. exchanged with the P-channel type transistors. In this case, the N-channel type transistors is used for the transfer/load transistors and the P-channel type transistors for the drive transistors and the source electrodes of the drive transistors are connected to the “H” power potential line. Using this memory cell, during the standby state, the potential of the word line is at “L” and the potential of the bit line is at “L” for holding data. Alternatively, the memory cell composing the N-channel type transistors may be used for both of the transfer/load transistors and the drive transistors. In this configuration, since only one conductivity type is used, the layout of the circuits on the semiconductor substrate can be actually easy.

Sixth Embodiment

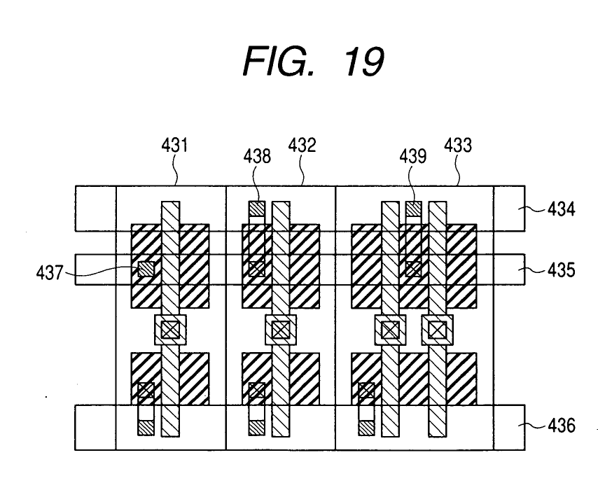

This embodiment is a variation of the third embodiment. In FIG. 9, a power switch circuit POWERCRT is formed on the SOI, while in this embodiment, DTMOS is used for the power switch circuit. FIG. 18 shows a circuit configuration using DTMOS as the power switch, which reduces the leakage current during standby state, in which the circuits do not operate. Circuit CRT(421) indicates a logic circuit, processing signals and then output them on operation state, 422 indicates a power line vssm connected mainly to the source electrodes of the N-channel type transistors of the circuit 421, 423 indicates a ground potential line vss, and 424 indicates the N-channel type transistor as a switch connecting the power line vssm and the power line vss, respectively. The circuit CRT(421) is, for example as shown in FIG. 9, a circuit including logics such as a CPU(305) a memory controller (304), and a bus control (306) and the like. The double gate (the gate electrode and the electrode on the SOI base substrate side) of the switch transistor 424 is controlled by signal on. The potential “H” of the signal on is equal to the potential “H” of the logic circuit. The switch transistor has the same structure as that of transistors comprising the logic circuit 421.

While the logic circuit 421 operates, the signal on puts the switch transistor 424 in on state and the power line vssm and the ground line vss are coupled, making the potential of vssm equal to the ground potential. During the standby state, when the logic circuit 421 does not operate, the signal on puts the switch transistor in an off state and the power line vssm is disconnected from the ground potential line vss, and the potential of vssm rises. Accordingly, the leakage current flowing through the logic circuit 421 is reduced, allowing power consumption to be decreased during the standby state. But latch and the like in the logic circuit, stored with data will be destructed. The logic circuit 421 has been defined as a circuit processing a signal and then outputs it, but a memory circuit such as SRAM can be included if the destruction of stored data is acceptable.

In conventional circuit including a switch transistor, a transistor with a thick insulating film was used for the switch transistor and while the switch transistor is on state, higher voltage is applied to the gate electrodes than that applied to the logic circuit. Thus, the leakage current of the switch transistor while it is off state and the resistance in the switch transistor while it is on state was minimized. But this required a transistor with a thick insulating film, which is not used in the logic circuit, and therefore such problems have arisen that space requirement increases and the increased process cost. In addition, since a high-voltage signal is needed as a control signal, the logic circuit must be provided at a position away from the switch transistor, increasing the space requirement.

In the case of the circuit configuration of the present embodiment, the same double gate type FD-SOI transistor used in the logic circuit is used for the switch transistor. For this reason, the process cost does not increase. Besides, since the potential of the signal on can be the same level as the potentials used for signal in the logic circuit, they can be provided at the positions in the vicinity one another. This means that the switch transistor can be disposed, with only the increase of area for the switch transistor itself.

Using the double gate type FD-SOI transistor for the switch transistor 424, an on-off ratio can be increased. Even if the potential of the control signal on is equal to that of the logic circuit, on current can be increased and the leakage current flowing while the circuit is in off state can be reduced. Note that in FIG. 18, DTMOS composing N-channel type MISFETs is used for the switch, but alternatively, DTMOS composing the P-channel type MISFETs may be disposed between the power line on the high potential side and the circuit, and also both of them may be combined.

FIG. 19 shows one example of logic circuit (421). 431 indicates an inverter cell, which high-speed operation is not required, 432 indicates an inverter, which high-speed operation is required, 433 indicates a NAND cell, which high-speed operation is required, 434 indicates a power line of a “H” potential, 435 indicates a power line of a potential lower than the “H” potential of 434, 436 indicates a ground potential line, and 437, 438, and 439 indicate the source electrodes of the P-channel type transistors in the cells 431, 432, and 433 or the metal contacts for connecting to the power line 434 or 435. The P-channel type transistors in the logic circuit (421) are formed on a common SOI base substrate. The N-channel type transistors in the logic circuit (421) are formed on a common SOI base substrate. If the threshold voltages can be formed suitable for both the P-channel type transistors and the N-channel type transistors, both can be formed on the same SOI base substrate.

Since the inverter cell 43 does not require high-speed operation, it is connected to a low-voltage line 435, and its operation speed is slower compared to the cell speed of the cell connected to a high-voltage line 434, but with a merit of smaller power consumption. Since the inverter cell 432 and the NAND cell are connected to the high-voltage power compared to the cell connected to the low-voltage power line 435, but operates faster. Thus, by connecting only the circuit, for which high-speed operation is required among the circuit, in which a plurality of logic cells are integrated, to the high-voltage power line 435, and by connecting the circuit, for which high-speed operation is not required to the low voltage power line 435, high-speed performance may be maintained with reduced power consumption.

With the conventional bulk CMOS, the potential of the substrate or the well must be changed according to the power voltage. This is because voltage difference between the power source and the substrate potential cause currents to flow through the PN junction between the substrate and the diffusion layer. Since the circuits, of which substrate or the well have different potentials, need to be laid apart from each other at a certain distance, the circuits having different power voltages cannot be laid adjacently to another unlike the to this embodiment. In fact, a plurality of voltage sources could not be used in single circuit. So when the power voltage is determined depending on the operation speed, the circuits not requiring such speed are also driven by applying the power voltage, consuming excess power.

According to this embodiment, since the double gate type FD-SOI is used for the transistors for configuring the circuit, the substrate and the diffusion layers are isolated, so a difference in potentials do not cause a current to flow there. For this reason, the potentials of the substrate and the power line can be set differently, achieving the configuration of this embodiment. Also MISFETs formed on a bulk, when two power sources, a high power voltage Vddh and a low power voltage Vddl, are used, the wells of the two power systems have to be separated. On the other hand with SOIs, the MISFETs of circuit blocks having two power systems can be formed on the same SOI base substrate. For example, P-channel type MISFETs formed on the bulk without the wells separated for each power systems, must use Vddh for a common well potential Vbp to avoid leakage current caused by a forward bias, as a result, a back bias is applied to the P-channel type MISFETs, to which Vssl is applied, which will drop its operation speed. In contrast, the MISFETs formed on SOIs will not cause problems of leakage current by a forward bias. Therefore, the MISFETs can be formed on the same SOI base substrate and apply a single voltage suitable for the SOI base substrate depending on the required performance, even though they are using a plurality of power systems.

As mentioned above, since the suitable threshold voltages can be set even if SRAM and the peripheral circuits are formed on the same SOI base substrate, making it possible to fully levelize the characteristics of the SOI with no deterioration in performance. In addition, these circuits can operate more stably at a lower voltage, operate at a higher speed with the same level of leakage current, and improve the resistance to soft errors.

Note that the Full Depletion type SOI described in the embodiments is those of which channel parts are fully depleted, but Partial Depletion (PD) SOI may be used if dispersion of the threshold voltage can be suppressed.

According to the present invention, a SOI substrate can be used to achieve a suitable threshold voltage for each circuit, making it possible to fully use the characteristics of the SOI substrate.

While the present invention has been described above in connection with the preferred embodiments, one of ordinary skill in the art would be enabled by this disclosure to make modifications to the various embodiments and still be within the scope and spirit of the present invention as recited in the appended claims.

What is claimed is:

1. A semiconductor device, comprising:
a plurality of word lines;
first and second bit lines; and
a plurality of memory cells, each of the plurality of memory cells having first and second P-channel type MISFETs, and third, fourth, fifth, and sixth N-channel type MISFETs,
wherein drains of the first and third MISFETs are connected to gates of the second and fourth MISFETs, gates of the first and third MISFETs are connected to drains of the second and fourth MISFETs, a source-drain path of the fifth MISFET is connected between said first bit line and the drain of the third MISFET, a source-drain path of the sixth MISFET is connected between said second bit line and the drain of the fourth MISFET,
wherein regions forming channels of the first to fourth MISFETs are in a floating state, and
wherein regions forming channels of the fifth and sixth MISFETs are coupled to a first wiring line supplying a potential.

2. The semiconductor device according to claim 1, wherein said semiconductor device is a semiconductor chip, having first and second semiconductor layers, and an insulating film provided between the first and second semiconductor layers,
wherein diffusion layers of the first to sixth MISFETs are formed in the first semiconductor layer, and
wherein regions forming channels of the first to sixth MISFETs are each separated by an insulating layer.

3. The semiconductor device according to claim 2,
wherein a potential of the region forming the channel of the fifth MISFET is controlled by a potential of a word line connected to the gate of the fifth MISFET,
a potential of the region forming the channel of the sixth MISFET is controlled by a potential of a word line connected to the gate of the sixth MISFET, and
a potential of the region forming the channels of the fifth and sixth MISFETs in a memory cell connected to a non-selected word line of the plurality of word lines is lower than the potential of the region forming the channels of the fifth and sixth MISFETs in a memory cell connected to a selected word line of the plurality of word lines.

4. The semiconductor device according to claim 2,
wherein while a word line is selected and a word line is not selected, a same potential is supplied to the first wiring line.

5. The semiconductor device, according to claim 1,
wherein said semiconductor device is a semiconductor chip having first and second semiconductor layers and an insulating layer in between the first and second semiconductor layers,
wherein a voltage larger than an operating voltage applied to the memory cell is applied to the second semiconductor layer,
wherein diffusion layers of the third to sixth MISFETs are formed in the first semiconductor layer, and
wherein the first and second MISFETs are vertical MISFETs, each of which has a source region, a channel region, and a drain region deposited above the first semiconductor layer.

6. A semiconductor device, comprising:
a memory cell having first and second load P-channel type MISFETs, first and second driver N-channel type MISFETs, and first and second transfer N-channel type MISFETs,
wherein gate and channel regions of the first transfer N-channel type MISFET is coupled to each another,
wherein gate and channel regions of the second transfer N-channel type MISFET are coupled to each another,
wherein gate and channel regions of the first load P-channel type MISFET are not coupled to each another,
wherein gate and channel regions of the second load P-channel type MISFET are not coupled to each another,
wherein gate and channel regions of the first driver N-channel type MISFET are not coupled to each another, and wherein gate and channel regions of the second driver N-channel type MISFET is not coupled to each another.

7. The semiconductor device according to claim 6, further comprising:
a plurality of word lines;
a plurality of bit lines; and
a plurality of said memory cells,
wherein a potential of the channel region of the first transfer N-channel type MISFET in a memory cell connected to the non-selected word line of the plurality of word lines is lower than a potential of the channel region of the first transfer N-channel type MISFET in the memory cell connected to a selected word line of the plurality of word lines, and
wherein said plurality of memory cells are formed on a SOI substrate.

8. The semiconductor device according to claim 7,
wherein a voltage larger than an operating voltage of the memory cells is applied to the SOI substrate, and
wherein the channel regions of the first and second driver N-channel type MISFETs and the first and second transfer N-channel type MISFETs are separated by insulating layers.

9. A semiconductor device, comprising:
a first semiconductor layer;
a second semiconductor layer; and
an insulating layer between the first and second semiconductor layers,
wherein diffusion layers of a plurality of first MISFETs are formed in the first semiconductor layer,
wherein a portion of said second semiconductor layer has a first semiconductor region, where said first semiconductor layer and said insulating layer are not covered,
wherein a supply region, which is of the same conductivity type and has a larger impurity density than said first semiconductor region, is formed in said first semiconductor region, and
wherein the threshold voltages of the plurality of first MISFETs are made to vary by supplying a voltage to the supply region.

10. The semiconductor device according to the clam 9,
wherein the supply region is formed in the shape of a ring surrounding a region covered with the first semiconductor layer and the insulating layer,
wherein in first semiconductor region the supply region and the second semiconductor region, which forms a PN junction with the second semiconductor layer, are formed,
wherein in the second semiconductor region a third semiconductor region, which forms a PN junction with the second semiconductor region, is formed,
wherein in the second semiconductor region a plurality of second MISFETs, in which their diffusion layers forms a PN junction with the second semiconductor region, are formed, and
wherein in the third semiconductor region a plurality of third MISFETs, in which their diffusion layers forms a PN junction with the third semiconductor region, are formed.

11. The semiconductor device according to claim 10,
wherein gate insulating films of the plurality of first and second MISFETs are formed by the same steps.

12. The semiconductor device according to claim 10,
wherein the second semiconductor layer is N-type, and
wherein a voltage applied to the supply region is higher than an operating voltage of the plurality of first MISFETs.

13. The semiconductor device according to claim 10,
wherein the first semiconductor layer includes a static memory cell, and
wherein the second and third semiconductor regions include I/O circuits.

14. The semiconductor device according to claim 13,
wherein a logic circuit is further formed in the first semiconductor layer, and
wherein a switch circuit for controlling an operating voltage of the logic circuit and an analog circuit are further formed in the second and third semiconductor regions.

15. A semiconductor device, formed on a semiconductor chip, comprising:
a first circuit portion including a plurality of first MISFETs of a first conductivity type and a plurality of second MISFETs of second conductivity type; and
a second circuit portion including a plurality of third MISFETs,
wherein the semiconductor chip includes a first conductivity type semiconductor substrate with an insulating layer embedded therein,
wherein the semiconductor substrate includes a first semiconductor region forming a PN junction with the semiconductor substrate, and a second semiconductor region of a second conductive type having a higher impurity density than an impurity density of the semiconductor substrate,
wherein the first semiconductor region includes a third semiconductor region forming a PN junction the semiconductor substrate,
wherein a semiconductor region on the insulating layer includes diffusion layers of the plurality of third MISFETs,
wherein diffusion layers of the plurality of first MISFETs form a PN junction with the first semiconductor region,
wherein diffusion layers of the plurality of second MISFETs form a PN junction with the third semiconductor region, and
wherein a first voltage is applied to the second semiconductor region.

16. The semiconductor device according to claim 15, wherein the first conductivity type is of N-type and the first voltage is higher than the operating voltage applied to the second circuit portion.

17. The semiconductor device according to claim 16,
wherein the second circuit portion includes a static type memory cell, and
wherein the first circuit portion includes an I/O circuit.

18. The semiconductor device according to claim 17,
wherein the second circuit portion further includes a logic circuit, and
wherein the first circuit portion further includes a switch circuit for controlling the operating voltage of the logic circuit.

19. The semiconductor device according to claim 18,
wherein gate electrodes of the plurality of third MISFETs are made of silicon germanium, and
wherein P-type dopants are implanted to gate electrodes of the plurality of third MISFETs of both P-channel and N-channel type.

20. The semiconductor device according to claim 17,
wherein the semiconductor substrate is formed by bonding silicon substrates together, having an insulating film therebetween, and
wherein the first to fourth semiconductor regions are formed in a portion of the bonded silicon substrate, where the silicon layer on the insulating film and the insulating film itself are removed by etching.

21. The semiconductor device according to claim 17,
wherein gate insulating films of the first to third MISFETs are formed by the same process.

22. The semiconductor device according to claim 16, further comprising:
a voltage step-down circuit made of the first and second MISFETs,
wherein the first voltage is supplied externally from a semiconductor chip,
wherein the first voltage is inputted to the voltage step-down circuit, and the operating voltage of the second circuit portion is an output from the voltage step-down circuit.

23. A semiconductor device, formed on a semiconductor substrate including a bulk portion and a SOI portion, comprising:
a logic circuit;
a switch circuit for a controlling operating voltage applied to the logic circuit; and
an I/O circuit,
wherein the switch circuit and the I/O circuit are formed in the bulk portion, and
wherein the logic circuit is formed in the SOI portion.

24. The semiconductor device according to claim 23, further comprising:
a SRAM memory cell; and a power circuit for generating the operating voltage of the SRAM memory cell,
wherein the memory cell is formed in the SOI portion, and
wherein the power circuit is formed in the bulk portion.

25. The semiconductor device according to claim 24,
wherein gate electrodes of MISFETs of P-type and N-conductivity type channels, of which diffusion layers are formed in the SOI portion, are made of silicon germanium and P-type dopants are implanted, and
wherein a substrate potential of the SOI portion is applied through a power supply region formed in the bulk portion.

26. A semiconductor device formed on a substrate including a first semiconductor layer, a second semiconductor, and an insulating film provided between the first and second semiconductors, comprising:
a logic circuit including a plurality of N-channel type first MISFETs and a plurality of P-channel type second MISFETs, and
a memory cell including N-channel type third, fourth, fifth, and sixth MISFETs and P-channel type seventh and eighth MISFETs,
wherein each of diffusion layers of the first to eight MISFETs is formed in the first semiconductor layer,
wherein gate electrodes of the first to eight MISFETs are made of silicon germanium, and are implanted by P-type dopants, and
wherein a voltage is applied to the second semiconductor layer.

27. The semiconductor device according to claim 26,
wherein the logic circuit has a word driver circuit driving a word line, and a sense amplifier circuit coupled to a pair of bit lines,
wherein gates of the third and four MISFETs are coupled to the word line,
wherein gates of the fifth and seventh MISFETs are coupled to drains of the sixth and eighth MISFETs,
wherein gates of the sixth and eighth MISFETs are coupled to drains of the fifth and seventh MISFETs, and
wherein potentials of channel regions of the third and fourth MISFETs vary by a potential of the word line.

28. The semiconductor device according to claim 26,
wherein a voltage higher than an operating voltage of the memory cell.

29. The semiconductor device according to claim 26,
wherein a portion of the second semiconductor layer includes a first region, in which the insulating film and the first semiconductor layer are not formed
wherein the first region includes an I/O circuit for inputting and outputting data externally from said semiconductor device.

30. The semiconductor device according to claim 28,
wherein a portion of the second semiconductor layer includes a first region, where the insulating film and the first semiconductor layer are not formed,
wherein the second semiconductor layer is of N-type, and
wherein a voltage is applied to the second semiconductor layer is applied through a power supply region formed in the first region.

31. The semiconductor device according to claim 30,
wherein a power circuit for generating an operating voltage of memory cells is further formed in the first region, and
wherein the power circuit has a function of dropping voltage inputted externally of the semiconductor device.

32. A semiconductor device, which includes a first semiconductor layer, a second semiconductor layer, and an insulating film between the first and second semiconductor layers, comprising:
a logic circuit including a plurality of N-channel type first MISFETs and a plurality of P-channel type second MISFETs, and
a memory cell including an N-channel type third, fourth, fifth, and sixth MISFETs, and P-channel type seventh, and eighth MISFETs,
wherein each of diffusion layers of the first to eighth MISFETs is formed in the first semiconductor layer,
wherein gate electrodes of the first and second MISFETs are made of silicon germanium and are implanted with P-type dopants,
wherein gate electrodes of the third to sixth MISFETs are made of polysilicon and are implanted with N-type dopants,
wherein gate electrodes of the seventh and eighth MISFETs are made of polysilicon and are implanted with P-type dopants, and
wherein a voltage is applied to the second semiconductor layer.

33. The semiconductor device according to claim 32,
wherein the logic circuit includes a word driver circuit for driving a word line, a decoder circuit, and a circuit for precharging bit lines,
wherein gates of the third and fourth MISFETs are coupled to the word line,
wherein gates of the fifth and seventh MISFETs are coupled to drains of the seventh and eighth MISFETs,
wherein gates of the sixth and eighth MISFETs are coupled to drains of the fifth and seventh MISFETs, and
wherein potentials of channel regions of the third and fourth MISFETs are controlled, and the channels regions of the fifth to eighth MISFETs are in a floating state.

34. The semiconductor device according to claim 33,
wherein a voltage higher than an operating voltage of the memory cells is applied to the second semiconductor layer.

35. The semiconductor device according to claim 34,
wherein the absolute value of a threshold voltage of the seventh MISFET is larger than the absolute value of a threshold voltage of the third MISFET.

36. The semiconductor device according to claim 31,
wherein the first to eighth MISFETs are enhancement type MISFETs, and
wherein the second semiconductor layer is of n-type.

37. A semiconductor device, comprising:
a plurality of word lines;
first and second bit lines; and
a plurality of memory cells,
wherein each of the plurality of memory cells having P-channel type first and second MISFETs and N-channel type third and fourth MISFETs,
wherein a source-drain path of the first MISFETs are formed between the first bit line and a drain of the third MISFET, a source-drain path of the second MISFET is formed between the second bit line and a drain of the fourth MISFET, and input and output terminals of the third and fourth MISFETs are coupled to each another,
wherein a voltage applied to a first SOI base substrate, where the first MISFET is formed, is controlled by drain voltage of the fourth MISFET, and
wherein a voltage applied to a second SOI base substrate, where the second MISFET is formed, is controlled by drain voltage of the third MISFET.

38. The semiconductor device according to claim 37,
wherein the third and fourth MISFETs of the plurality of memory cells are formed on a common SOI base substrate.

39. A semiconductor device comprising:
a logic circuit; and
a switch circuit for controlling an operating voltage of the logic circuit,
wherein transistors included in the logic circuit and the switch circuit are formed on a SOI substrate,
wherein a voltage of the SOI substrate, on which the first transistor included in the switch circuit is formed, is controlled by a signal input to a gate of the first transistor.

40. A semiconductor device, comprising:
a first power source and a second power source;
a first circuit including a plurality of first MISFETs driven by the first power source; and
a second circuit having a plurality of second MISFETs driven by the second power source,
wherein the plurality of first MISFETs and the plurality of second MISFETs are formed on a common SOI base substrate.

41. The semiconductor device according to claim 40,
wherein channel regions of the plurality of first and second MISFETs are individually controlled by two gate electrodes which are controlled by the application of a first voltage to a common SOI base substrate.
